(19) United States
(12) Patent Application Publication
(10) Pub. No.: US 2023/0325700 A1
(43) Pub. Date: Oct. 12, 2023

(54) QUANTUM CHIP STRUCTURE, DETERMINING METHOD, DEVICE AND STORAGE MEDIUM

(71) Applicant: Beijing Baidu Netcom Science Technology Co., Ltd., Beijing (CN)

(72) Inventors: Lijing Jin, Beijing (CN); Yuao Chen, Beijing (CN)

(73) Assignee: Beijing Baidu Netcom Science Technology Co., Ltd., Beijing (CN)

(21) Appl. No.: 17/983,163

(22) Filed: Nov. 8, 2022

(30) Foreign Application Priority Data
Apr. 12, 2022 (CN) 202210398029.4

(51) Int. Cl. G06N 10/40; H03K 17/92

(52) U.S. Cl. CPC G06N 10/40; H03K 17/92

(57) ABSTRACT

Provided are a quantum chip structure, a determining method, a device and a storage medium, and relates to the field of computer technology, and in particular, to the field of quantum computation. The quantum chip structure includes: a ring structure composed of n center qubits, where two adjacent center qubits in the ring structure are connected through a coupler; and n is a natural number greater than or equal to 3; and two-linear structures drawn from a center qubit Qᵢ toward outside of the ring structure; where a first linear structure in the two-linear structures contains aᵢ first qubits; and a second linear structure in the two-linear structures contains bᵢ second qubits. In this way, a quantum chip structure with high connectivity is obtained.

### CROSS-REFERENCE TO RELATED APPLICATIONS

The present application claims priority to Chinese Patent Application No. CN202210398029.4, filed with the China National Intellectual Property Administration on Apr. 12, 2022, the disclosure of which is hereby incorporated herein by reference in its entirety.

### TECHNICAL FIELD

The present disclosure relates to the field of computer technologies, and in particular, to the field of quantum computation.

### BACKGROUND

There are many factors to measure the performance of a quantum chip, and the connectivity is one of the key indicators. Therefore, how to design a superconducting quantum chip with the connectivity as high as possible on the quantum hardware level has become a very important issue.

### SUMMARY

The present disclosure provides a quantum chip structure, a determining method and apparatus, a device and a storage medium.

According to an aspect of the present disclosure, provided is a quantum chip structure, including: a ring structure composed of n center qubits, where two adjacent center qubits in the ring structure are connected to each other through a coupler, and n is a natural number greater than or equal to 3; and a two-linear structure drawn from the center qubit Qᵢ toward outside of the ring structure, where a first linear structure of the two-linear structure includes aᵢ first qubits, a second linear structure of the two-linear structure includes bᵢ second qubits, where aᵢ is a natural number greater than or equal to 1, bᵢ is a natural number greater than or equal to 1 and i is a natural number greater than or equal to 0 and less than or equal to n−1.

According to another aspect of the present disclosure, provided is a determining method, including: obtaining a total number of qubits N in a quantum chip structure to be determined; where the quantum chip structure is the quantum chip structure described above; and determining a target mapping distance of the quantum chip structure based on at least the total number of qubits N, where the target mapping distance is determined based on a sub-mapping distance of a pair of target qubits in the quantum chip structure, and the sub-mapping distance represents a minimum number of couplers between one target qubit of the pair of target qubits and the other target qubit of the pair of target qubits; the target qubit of the pair of target qubits is one of: the center qubit in the ring structure of the quantum chip structure, the first qubit in the first linear structure corresponding to the center qubit Qᵢ, and the second qubit in the second linear structure corresponding to the center qubit Qᵢ, where i is a natural number greater than or equal to 0.

According to yet another aspect of the present disclosure, provided is a determining apparatus, including: an obtaining module configured to obtain a total number of qubits N in a quantum chip structure to be determined; where the quantum chip structure is the quantum chip structure described above; and a first determining module configured to determine a target mapping distance of the quantum chip structure based on at least the total number of qubits N, where the target mapping distance is determined based on a sub-mapping distance of a pair of target qubits in the quantum chip structure, and the sub-mapping distance represents a minimum number of couplers between one target qubit of the pair of target qubits and the other target qubit of the pair of target qubits; the target qubit of the pair of target qubits is one of: the center qubit in the ring structure of the quantum chip structure, the first qubit in the first linear structure corresponding to the center qubit Qᵢ, and the second qubit in the second linear structure corresponding to the center qubit Qᵢ, where i is a natural number greater than or equal to 0.

According to yet another aspect of the present disclosure, provided is an electronic device, including: at least one processor; and a memory connected in communication with the at least one processor; where the memory stores an instruction executable by the at least one processor, and the instruction, when executed by the at least one processor, enables the at least one processor to execute the method described above.

According to yet another aspect of the present disclosure, provided is a quantum chip, including the quantum chip structure described above.

According to yet another aspect of the present disclosure, provided is a quantum computer, including the quantum chip described above, and an external control system connected with the quantum chip.

According to yet another aspect of the present disclosure, provided is a non-transitory computer-readable storage medium storing a computer instruction thereon, and the computer instruction is used to cause a computer to execute the method described above.

According to yet another aspect of the present disclosure, provided is a computer program product including a computer program, and the computer program implements the method described above, when executed by a processor.

In this way, a quantum chip structure with high connectivity is obtained.

It should be understood that the content described in this part is not intended to identify key or important features of embodiments of the present disclosure, nor is it used to limit the scope of the present disclosure. Other features of the present disclosure will be easily understood by the following description.

### BRIEF DESCRIPTION OF THE DRAWINGS

The accompanying drawings are used to better understand the present solution, and do not constitute a limitation to the present disclosure.

FIG. 1 is a schematic structural diagram of a quantum chip structure according to the embodiments of the present disclosure.

FIG. 2 is a first schematic flowchart of a determining method according to the embodiments of the present disclosure.

FIG. 3 is a second schematic flowchart of a determining method according to the embodiments of the present disclosure.

FIG. 4 is a third schematic flowchart of a determining method according to the embodiments of the present disclosure.

FIGS. 5(a) and 5(b) are structural diagrams of a quantum chip structure in a specific example according to the embodiments of the present disclosure.

FIGS. 6(a) to 6(c) are structural diagrams of a quantum chip structure in another specific example according to the embodiments of the present disclosure.

FIGS. 7(a) to 7(e) are schematic diagrams of a wiring flow of a quantum chip structure according to the embodiments of the present disclosure.

FIG. 8 is a comparison diagram of the connectivity between the quantum chip structure according to the embodiments of the present disclosure and the existing solution.

FIG. 9 is a schematic structural diagram of a determining apparatus according to the embodiments of the present disclosure.

FIG. 10 is a block diagram of an electronic device used to implement the determining method of the embodiments of the present disclosure.

### DETAILED DESCRIPTION

Hereinafter, descriptions to exemplary embodiments of the present disclosure are made with reference to the accompanying drawings, include various details of the embodiments of the present disclosure to facilitate understanding, and should be considered as merely exemplary. Therefore, those having ordinary skill in the art should realize, various changes and modifications may be made to the embodiments described herein, without departing from the scope and spirit of the present disclosure. Likewise, for clarity and conciseness, descriptions of well-known functions and structures are omitted in the following descriptions.

In recent years, the quantum computation has become an important direction of research and development in academia and industry. Compared with traditional computation, the quantum computation has shown significant advantages in solving problems such as decomposition of large numbers, and is also of great significance to the frontier research such as quantum many-body system and quantum chemical simulation. In terms of hardware implementation, the quantum computation has a variety of technical solutions, such as superconducting quantum circuit, ion trap, photon, or the like. Benefiting from the advantages of long decoherence time, easy manipulation and reading, and strong expandability, the superconducting quantum circuit is considered to be the most promising candidate for quantum computing hardware in the industry. Therefore, as a key part of superconducting quantum computation (i.e., quantum computation performed by using the superconducting quantum circuit), the design, development and fabrication of the superconducting quantum chip integrating a plurality of superconducting qubits are of great significance.

In practical applications, there are many factors to measure the performance of a quantum chip (such as superconducting quantum chip), and the connectivity is one of the key indicators. Here, the so-called connectivity refers to the degree of connectivity between one qubit and other remaining qubits in the quantum chip (such as superconducting quantum chip). Taking a superconducting quantum chip as an example, different from the ion trap quantum computation, the superconducting qubits can only be coupled with adjacent superconducting qubits in a superconducting quantum circuit. Due to this limitation, the two-superconducting qubit gate is also limited to be realized between adjacent superconducting qubits. However, in practice, in order to realize the quantum gate operation between any two superconducting qubits, the coupling between non-adjacent superconducting qubits is required. Based on this, it has become a very important subject to map a quantum circuit at the algorithm level (i.e., a logical quantum circuit) into a physical quantum circuit at the physical level that meet the physical constraints of the superconducting quantum chip. Although such mapping solves the problem to a certain extent, the price it brings is the need to additionally introduce a large number of two-bit quantum gates (that is, two-superconducting qubit gates), which undoubtedly greatly reduces the efficiency and accuracy of computation. Therefore, how to design a superconducting quantum chip with the connectivity as high as possible from the quantum hardware level has become a very important issue.

Moreover, in the design process of the superconducting quantum chip, the feasibility and yield of the subsequent micro-nano processing technology also need to be considered in advance (it can be understood that the preparation of the superconducting quantum chip usually requires the micro-nano processing technology). At present, there is a 2D (2 Dimensional) micro-nano processing technology in the industry, that is, all core devices (such as qubits, read resonators, etc.) and various connection lines (such as read lines, control lines) are placed on the same 2D plane. In the 2D micro-nano processing technology, if two connection lines have to intersect, the Air-bridge process needs to be further introduced. In recent years, the more advanced 3D (3 Dimensional) micro-nano processing technology has also been gradually applied to the preparation of large-scale extendable superconducting quantum chips; by using the 3D micro-nano processing technology, the core devices and connection lines are usually distributed in different layers, and then the different layers are connected together by the flip-chip technology or Through Silicon Via (TSV) technology.

Although the 3D micro-nano processing technology has brought new ideas for the subsequent large scale in the practice and application of superconducting quantum chips, the yield is overly dependent on the maturity of the new technology. Therefore, it is considered whether the feasibility, yield and strong connectivity can be taken into account, in the case of using the more mature 2D micro-nano processing technology and not using the air bridge (here, the use of the air bridge in the 2D micro-nano processing technology may also lead to crosstalk or decrease in yield).

Based on this, the solution of the present disclosure provides a general quantum chip structure, which can realize the strong connectivity between qubits and also take into account the feasibility and yield without using the air bridge process. Compared with the common 2D design solutions in the industry, the solution of the present invention presents a significant advantage in connectivity; and is even better than some solutions designed based on 3D process in the industry. Moreover, the solution of the present disclosure can also efficiently determine a quantum chip structure with high connectivity after the total number of qubits is given.

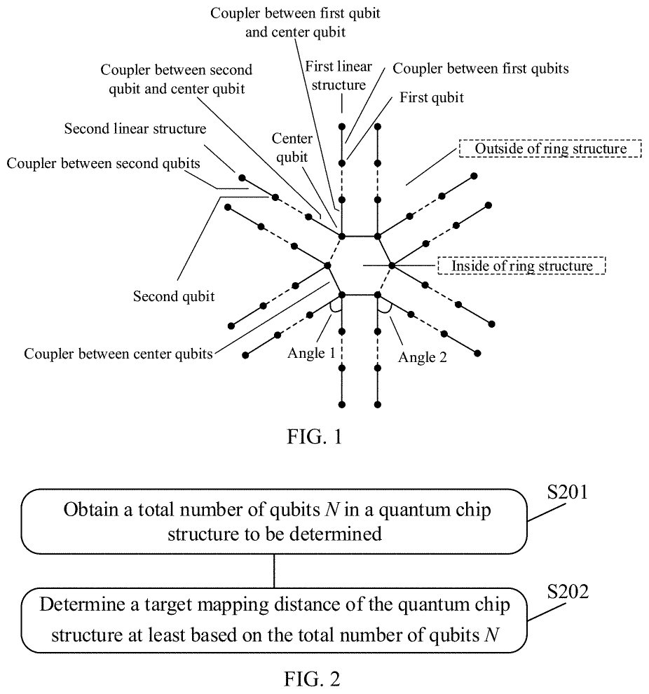

Specifically, FIG. 1 is a schematic structural diagram of a quantum chip structure according to the embodiments of the present disclosure. Specifically, as shown in FIG. 1, the quantum chip structure includes: a ring structure composed of n center qubits, where two adjacent center qubits in the ring structure are connected to each other through a coupler (as shown by solid lines in the ring structure in FIG. 1); and n is a natural number greater than or equal to 3; and a two-linear structure drawn from the center qubit Qᵢ toward outside of the ring structure; where a first linear structure of the two-linear structure includes aᵢ first qubits; and a second linear structure of the two-linear structure includes bᵢ second qubits.

Here, aᵢ is a natural number greater than or equal to 1, bᵢ is a natural number greater than or equal to 1; and i is a natural number greater than or equal to 0 and less than or equal to n−1.

Here, the outside of the ring structure refers to any direction toward the outside of the ring structure.

It should be noted that the linear structure described in the solution of the present disclosure may be a straight line structure, a curved structure, or a wavy line structure, etc., which is not exhaustive in the solution of the present disclosure. In addition, the length of the linear structure of the solution of the present disclosure can be determined based on the number of qubits on the linear structure in the actual design process; the solution of the present disclosure does not limit the included angle (such as Angle 1 shown in FIG. 1) between two-linear structures drawn from the same center qubit either. Similarly, different included angles, such as Angle 1 and Angle 2, may be the same or different, which is not limited either in the solution of the present disclosure.

In a specific example, the coupler may also be implemented by a qubit, and its core function is to adjust the coupling strength between two connected qubits (such as two connected center qubits, or two connected first qubits, or two connected second qubits, etc.).

Here, it can be understood that “center” in the center qubit, “first” in the first qubit and “second” in the second qubit described in the solution of the present disclosure are not used to limit the solution of the present disclosure, but only for the purpose of describing the quantum chip structure clearly; and in practical applications, the types of qubits selected by the three may be the same or different, which is not limited in the solution of the present disclosure.

It can be understood that the ring structure and the linear structure shown in FIG. 1 are only an example, and are not intended to limit the solution of the present disclosure.

Thus, compared with the common quantum chip design solutions in the industry, the solution of the present disclosure can be implemented by a simple micro-nano processing technology. For example, only the 2D micro-nano processing technology is required to complete the quantum chip structure provided in the solution of the present disclosure, and the air bridge process is not used in the whole process. The process is simple, the yield is high, and the cost is relatively low. Moreover, the quantum chip structure of the solution of the present disclosure also has the high connectivity, thus providing structural support for the subsequent design of a high-performance quantum chip.

Furthermore, since the linear structures of the solution of the present disclosure are drawn out toward the outside of the ring structure, the space layout is reasonable and the space utilization rate is large. Compared with the 2D solution in the industry scene, the solution of the present disclosure fully utilizes the entire space and leaves sufficient space to provide convenience for the subsequent arrangement of the reading resonator, reading line and control line. Moreover, the integration level of the quantum chip structure is also high.

Furthermore, the solution of the present disclosure does not limit the number of center qubits, first qubits and second qubits, and has the strong expandability.

In a specific example of the solution of the present disclosure, a first qubit adjacent to the center qubit Qᵢ in the first linear structure is connected to the center qubit Qᵢ through a coupler; and/or, a second qubit adjacent to the center qubit Qᵢ in the second linear structure is connected to the center qubit Qᵢ through a coupler.

That is, in an example, the first qubit adjacent to the center qubit Qᵢ in the first linear structure (that is, the qubit at the first place in the first linear structure) is connected to the center qubit Qᵢ through a coupler. In another example, the second qubit adjacent to the center qubit Qᵢ in the second linear structure (that is, the qubit at the first place in the second linear structure) is connected to the center qubit Qᵢ through a coupler. Alternatively, as shown in FIG. 1, the first qubit adjacent to the center qubit Qᵢ in the first linear structure (the qubit at the first place in the first linear structure) is connected to the center qubit Qᵢ through a coupler; and the second qubit adjacent to the center qubit Qᵢ in the second linear structure (the qubit at the first place in the second linear structure) is connected to the center qubit Qᵢ through a coupler.

It can be understood that FIG. 1 is only exemplary, and the qubits may also be connected through other structures in practical applications, which are not exhaustive in the solution of the present disclosure.

Thus, compared with the common quantum chip design solutions in the industry, the solution of the present disclosure can be implemented by a simple micro-nano processing technology. For example, only the 2D micro-nano processing technology is required to complete the quantum chip structure provided in the solution of the present disclosure, and the air bridge process is not used in the whole process. Moreover, the quantum chip structure of the solution of the present disclosure also has the high connectivity, thus providing structural support for the subsequent design of a high-performance quantum chip.

In a specific example of the solution of the present disclosure, when there are two or more of the first qubits in the first linear structure, two adjacent first qubits are connected to each other through a coupler; and/or, when there are two or more of the second qubits in the second linear structure, two adjacent second qubits are connected to each other through a coupler.

That is, in an example, two adjacent first qubits in the first linear structure are connected to each other through a coupler. In another example, two adjacent second qubits in the second linear structure are connected to each other through a coupler. Alternatively, as shown in FIG. 1, two adjacent first qubits in the first linear structure are connected to each other through a coupler, and two adjacent second qubits in the second linear structure are connected to each other through a coupler.

Here, it is worth noting that, as shown in FIG. 1, in the scenario where two adjacent qubits in the quantum chip structure are connected through a coupler, the total number of qubits, i.e., the total number of the center qubits, the first qubits and the second qubits in the quantum chip structure is the same as the total number of couplers in the quantum chip structure.

It can be understood that, when there are a plurality of qubits in the linear structure of the solution of the present disclosure, the spacing between qubits, such as the first spacing between the first qubits in the first linear structure (or the second spacing between the second qubits in the second linear structure) may be set based on actual design requirements, which is not limited in the solution of the present disclosure. The same applies to the spacing (such as the first spacing, the second spacing) between qubits in different linear structures, and the first spacings (or second spacings) corresponding to different center qubits may also be the same or different, which is not limited in the solution of the present disclosure.

Thus, compared with the common quantum chip design solutions in the industry, the solution of the present disclosure can be implemented by a simple micro-nano processing technology. For example, only the 2D micro-nano processing technology is required to complete the quantum chip structure provided in the solution of the present disclosure, and the air bridge process is not used in the whole process. Moreover, the quantum chip structure of the solution of the present disclosure also has the high connectivity, thus providing structural support for the subsequent design of a high-performance quantum chip.

In a specific example of the solution of the present disclosure, the ring structure is a convex polygon, the center qubit in the ring structure is vertex of the convex polygon, the coupler connecting the two adjacent center qubits is a side of the convex polygon. The center area as shown in FIG. 1 forms a convex n-gon. Here, it can be understood that the sides in the convex n-gon, that is, spacings between two adjacent center qubits, may be the same or different, which is not limited in the solution of the present disclosure. FIG. 1 is only an example, and this is not exhaustive in the solution of the present disclosure.

Thus, compared with the common 2D solution in the industry, the quantum chip structure described in the solution of the present disclosure has a reasonable space layout and a large space utilization rate, fully utilizes the entire space, and provides convenience for the subsequent arrangement of the reading resonator, reading line and control line. At the same time, the integration level of the quantum chip structure is also higher.

In a specific example of the solution of the present disclosure, the convex polygon is a regular polygon. That is, in this example, the spacings between two adjacent center qubits are the same.

Thus, compared with the common 2D solution in the industry, the quantum chip structure described in the solution of the present disclosure has a reasonable space layout and a large space utilization rate, fully utilizes the entire space, and provides convenience for the subsequent arrangement of the reading resonator, reading line and control line. At the same time, the integration level of the quantum chip structure is also higher.

In a specific example of the solution of the present disclosure, linear structures drawn from different center qubits do not intersect. It can be understood that, as shown in FIG. 1, except that the two-linear structure drawn from the center qubit, such as the first linear structure and the second linear structure drawn from the center qubit Qᵢ (i ranges from 0 to n−1), have an intersection point (which is the center qubit Qᵢ), the first linear structures drawn from different center qubits do not intersect, the second linear structures drawn from different center qubits do not intersect, the first linear structure drawn from a center qubit does not intersect with the second linear structure drawn from another center qubit, and similarly the second linear structure drawn from a center qubit does not intersect with the first linear structure drawn from another center qubit either. Thus, the air bridge process is not used in the whole process, avoiding crosstalk to the greatest extent. Moreover, compared with the common quantum chip design solutions, only the 2D micro-nano processing technology is required to complete the quantum chip structure provided in the solution of the present disclosure. The process flow is more mature and simpler, and the yield is high and the fabrication cost is low.

In a specific example of the solution of the present disclosure, the number aᵢ of first qubits in the first linear structure drawn from the center qubit Qᵢ is the same as the number bᵢ of second qubits in the second linear structure drawn from the center qubit Qᵢ.

That is to say, the numbers of qubits in two-linear structures drawn from the same center qubit are the same, thus improving the connectivity of the quantum chip structure effectively. Here, it can be understood that the numbers of first qubits corresponding to different center qubits, such as the number aᵢ of first qubits corresponding to the center qubit Qᵢ and the number aⱼ of first qubits corresponding to the center qubit Qⱼ (j≠i), are the same or may be different. Similarly, the numbers of second qubits corresponding to different center qubits, such as the number bᵢ of second qubits corresponding to the center qubit Qᵢ and the number bⱼ of second qubits corresponding to the center qubit Qⱼ (j≠i), are the same or different.

Alternatively, in an example, a difference between the number aᵢ of first qubits in the first linear structure drawn from the center qubit Qᵢ and the number bᵢ of second qubits in the second linear structure drawn from the center qubit Qᵢ is less than or equal to a preset threshold. That is to say, the difference between the qubits in the two-linear structure that are drawn from the same center qubit is less than the preset threshold. For example, the preset threshold is 1 or 2 or the like, and at this time, the difference between the qubits in the two-linear structure that are drawn from the same center qubit is less than or equal to 1 or 2. Thus, it is convenient to effectively adjust the connectivity of the quantum chip structure by regulating the difference between the first qubits and the second qubits, thereby laying a foundation for effectively improving the connectivity of the quantum chip structure.

In an example, the difference between the numbers of first qubits corresponding to different center qubits (that is, the difference between aᵢ and aⱼ) is less than or equal to the preset threshold, and the difference between the numbers of second qubits corresponding to different center qubits (for example, the difference between bᵢ and bⱼ) is less than or equal to the preset threshold.

It can be understood that the relationship between the first qubit and the second qubit corresponding to the same center qubit, the relationship between the first qubits corresponding to different center qubits, and the relationship between the second qubits corresponding to different center qubits may have various combination forms based on the above description, which are not exhaustive here, as long as the quantum chip structure with the ring structure and the linear structure is within the protection scope of the solution of the present disclosure.

Furthermore, it can also be understood that the solution of the present disclosure does not specifically limit the specific preset threshold, which may be set based on actual requirements or based on the requirements for connectivity.

In a specific example of the solution of the present disclosure, for a single qubit, it is usually necessary to connect to an external control system, for example, the qubits is connected to the external control system through a qubit control line (such as a magnetic flux control line, or a microwave control line, or a magnetic flux control line and a microwave control line), so as to realize the manipulation of the qubit. Moreover, in the quantum chip structure with the coupler structure, each coupler (which may be regarded as a qubit that can only adjust the frequency) also needs a coupler control line connected to the external control system. Based on this, the quantum chip structure further includes the following structures: a qubit control line, a coupler control line and a coupler control line.

The qubit control line is configured to connect a target qubit with the external control system, where the target qubit is one of: the center qubit, the first qubit and the second qubit. In practical applications, each target qubit (for example, the center qubit, or the first qubit, or the second qubit) leads out a qubit control line, such as a magnetic flux control line or a microwave control line. For another example, each target qubit (for example, the center qubit, or the first qubit, or the second qubit) leads out two qubit control lines, of which one is a magnetic flux control line and the other is a microwave control line. It can be understood that the wiring mode of the qubit control line is related to the specific structure of the target qubit, which is not limited in the present disclosure, thus facilitating the manipulation of the target qubit.

The coupler control line is configured to connect a coupler with the external control system; for example, each coupler (including a coupler connecting two adjacent center qubits, a coupler connecting two adjacent first qubits, a coupler connecting two adjacent second qubits, a coupler connecting a center qubit with a first qubit adjacent to the center qubit, and a coupler connecting a center qubit with a second qubit adjacent to the center qubit) may lead out a coupler control line, thus facilitating the manipulation of the coupler.

The read resonator is configured to couple with the target qubit. For example, a read resonator is arranged for each target qubit, thus facilitating to read the target qubit.

In this way, it is convenient to realize the connection with the external control system based on the qubit control line, the coupler control line and the read resonator, to lay a foundation for realizing the control of each qubit or coupler in the quantum chip structure through the external control system.

In a specific example of the solution of the present disclosure, the quantum chip structure further includes: a read line configured to connect a plurality of read resonators. In this way, the signal readout of the plurality of readout resonators is achieved by the read line.

In a specific example of the solution of the present disclosure, the center qubit is a computing qubit. The computing qubit refers to a qubit used for computing process, so as to improve the computing capability of the obtained quantum chip structure.

In a specific example of the solution of the present disclosure, the first qubit is a computing qubit; and/or, the second qubit is a computing qubit. For example, the first qubit is a computing qubit, or the second qubit is a computing qubit, or both the first qubit and the second qubit are computing qubits, thus meeting the computing requirement and improving the computing power of the obtained quantum chip structure.

Here, in a specific example, the center qubit, the first qubit and the second qubit are all computing qubits.

In a specific example of the solution of the present disclosure, at least one of the center qubit, the first qubit and the second qubit is a superconducting qubit.

That is, in one approach, the center qubit may be a superconducting qubit; in another approach, the first qubit may be a superconducting qubit; and in yet another approach, the second qubit may be a superconducting qubit. Alternatively, in practical applications, a combination of two or more of the above approaches may also be possible, that is, the center qubit, the first qubit and the second qubit are all superconducting qubits, which is not exhaustive here.

In a specific embodiment, the center qubit, the first qubit and the second qubit are all superconducting qubits, and at the same time, the coupler may also be specifically a superconducting qubit. At this time, the obtained quantum chip structure is a superconducting quantum chip structure.

It should be noted that the superconducting qubits described in the solution of the present disclosure refer to qubits prepared from superconducting materials. Correspondingly, in the case where the qubits in the quantum chip structure are superconducting qubits, the quantum chip structure is a superconducting quantum chip structure; and further, a quantum chip obtained based on the superconducting quantum chip structure is also a superconducting quantum chip. It can be understood that the components used in the superconducting quantum structure here are all prepared from superconducting materials, so as to lay the foundation for obtaining the superconducting quantum chip with high connectivity.

Thus, compared with the common quantum chip design solutions in the industry, the solution of the present disclosure has the following significant advantages.
1. The micro-nano processing technology is relatively simple; the solution of the present disclosure only needs the 2D micro-nano processing technology to complete the quantum chip structure described in the solution of the present disclosure, and there is no need to use the air bridge process in the entire process. The process is simple, the yield is high, and the cost is relatively low.
2. The qubits have the strong connectivity. Even under the limitations of the 2D micro-nano process with no air bridge, the quantum chip structure provided in the solution of the present disclosure still has the strong connectivity. Moreover, benefiting from the strong connectivity, the solution of the present disclosure can provide structural support for designing the high-performance quantum chip. It can be found from further analysis that the connectivity of the quantum chip structure of the solution of the present disclosure is even better than some 3D solutions in the industry.
3. The space layout is more reasonable and the space utilization rate is greater. Compared with the common 2D solution in the industry, the solution of the present disclosure fully utilizes the entire space, and leaves sufficient space for the subsequent design of the read resonator, reading line and control line; and the overall integration is higher.
4. The expansibility is strong. The solution of the present disclosure is not limited to a specific design solution, but a series of design solutions with similar structures. After calculation, it can be seen that the quantum chip structure of the solution of the present disclosure still has the excellent connectivity even if it is extended to thousands of qubits.

The solution of the present disclosure also provides a determining method, as shown in FIG. 2, including the followings.

Step S201: obtaining a total number of qubits N in a quantum chip structure to be determined; where the quantum chip structure is any quantum chip structure described above. The quantum chip structure may refer to FIG. 1 and will not be repeated here.

Step S202: determining a target mapping distance of the quantum chip structure based on at least the total number of qubits N, where the target mapping distance is determined based on a sub-mapping distance of a pair of target qubits in the quantum chip structure, and the sub-mapping distance represents a minimum number of couplers between one target qubit of the pair of target qubits and the other target qubit of the pair of target qubits; the target qubits of pair of target qubits is one of: the center qubit in the ring structure of the quantum chip structure, the first qubit in the first linear structure corresponding to the center qubit Qᵢ, and the second qubit in the second linear structure corresponding to the center qubit Qᵢ, where i is a natural number greater than or equal to 0. It can be understood that the target qubit is any qubit in the quantum chip structure.

Here, the sub-mapping distance is the minimum number of couplers contained in a feasible path (i.e., a passage) connecting two target qubits (for example, the two target qubits of the pair of target qubits).

Thus, the solution of the present disclosure can obtain a quantum chip structure with high connectivity in the case of determining the required total number of quantum bits, to provide structural support for the subsequent design of a high-performance quantum chip.

Moreover, compared with the common quantum chip design solutions in the industry, the quantum chip structure can be implemented by a simple micro-nano processing technology. For example, only the 2D micro-nano processing technology is required to realize the quantum chip structure of the solution of the present disclosure, and the air bridge process is not used in the whole process. At the same time, the quantum chip structure also has the high connectivity.

Furthermore, since the linear structures of the solution of the present disclosure are drawn out toward the outside of the ring structure, the space layout of the obtained quantum chip structure is reasonable and the space utilization rate is large. Compared with the 2D solution in the industry scene, the solution of the present disclosure fully utilizes the entire space and leaves sufficient space to provide convenience for the subsequent arrangement of the reading resonator, reading line and control line. At the same time, the integration level of the quantum chip structure is also high. Furthermore, the solution of the present disclosure does not limit the number of center qubits, first qubits and second qubits, so the expandability is strong.

In an example, the target mapping distance may also be output synchronously. Further, the quantum chip structure corresponding to the target mapping distance may also be output. Thus, a visual structure diagram is provided, to provide the support for the subsequent preparation of the quantum chip structure.

In a specific example of the solution of the present disclosure, the pair of target qubits is an ordered target qubit pair. In this example, the ordered target qubit pair means that two target qubits in the target qubit pair are ordered, that is, there is an order relationship; for example, the target qubit Qᵢ and the target qubit Qⱼ are a target qubit pair, and at this time, when the target qubit Qᵢ is different from the target qubit Qⱼ (that is, i≠j), the pair of target qubits (Qᵢ, Qⱼ) and the pair of target qubits (Qⱼ, Qᵢ) are different due to different orders of the target qubit Qᵢ and the target qubit Qⱼ. Here, j is a natural number greater than or equal to 0 and less than or equal to n−1.

It is worth noting that the sub-mapping distance from a target qubit to itself is 0, that is, the sub-mapping distance of the pair of target qubits (Qᵢ, Qᵢ) is 0.

In practical applications, the ordered target qubit pair may simultaneously use two counters to traverse all qubits (including the center qubits, the first qubits and the second qubits) in the quantum chip structure. In this way, all ordered pairs of target qubits in the quantum chip structure can be obtained by traversal based on two counters, to lay the foundation for obtaining the target mapping distance.

Thus, the foundation for obtaining a quantum chip structure with high connectivity is laid, and at the same time, a quantifiable solution is provided.

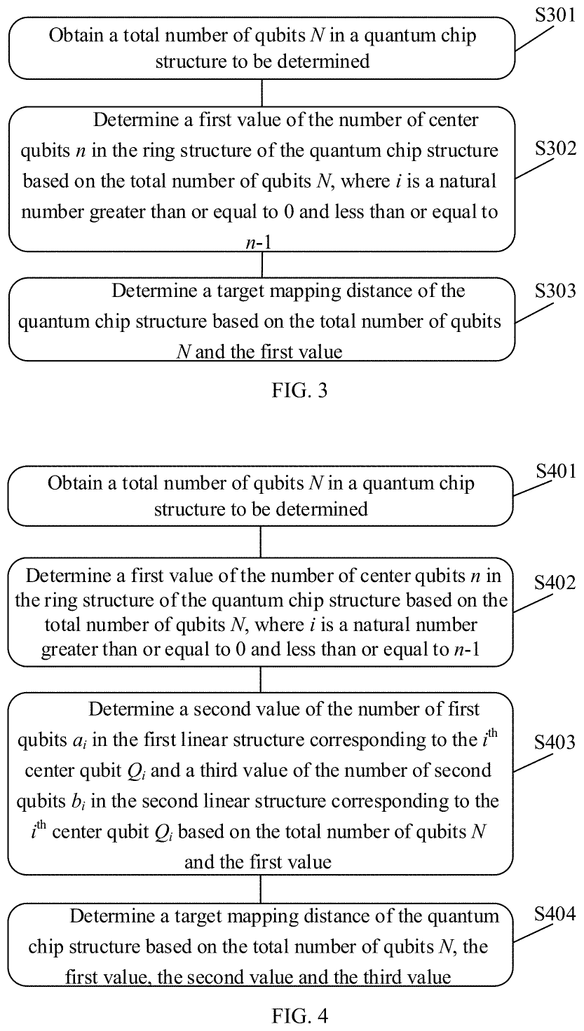

In a specific example of the solution of the present disclosure, as shown in FIG. 3, the method includes the followings.

Step S301: obtaining a total number of qubits N in a quantum chip structure to be determined; where the quantum chip structure is the quantum chip structure described above. The quantum chip structure may refer to FIG. 1 and will not be repeated here.

Step S302: determining a first value of the number of center qubits n in the ring structure of the quantum chip structure based on the total number of qubits N, where i is a natural number greater than or equal to 0 and less than or equal to n−1.

In a specific example, the first value of the number of center qubits n is one of: └\sqrt{2N}┘−1, └\sqrt{2N}┘, and └\sqrt{2N}┘+1.

That is, the first value of n may be specifically └\sqrt{2N}┘−1 or └\sqrt{2N}┘ or └\sqrt{2N}┘+1. or at least two or three thereof. Here, └\sqrt{2N}┘ represents the largest integer not greater than \sqrt{2N}. Thus, a simple and feasible value scheme of n is provided, to lay the foundation for obtaining the quantum chip structure with high connectivity.

It can be understood that the above-mentioned value of n is only a specific example, and other values may also be possible in practical applications, which are not exhaustive here and will not be limited in the solution of the present disclosure.

Step S303: determining a target mapping distance of the quantum chip structure based on the total number of qubits N and the first value, where the target mapping distance is determined based on a sub-mapping distance of the pair of target qubits in the quantum chip structure, and the sub-mapping distance represents a minimum number of couplers between one target qubit of the pair of target qubits and the other target qubit of the pair of target qubits; the target qubit in the pair of target qubits is one of: the center qubit in the ring structure of the quantum chip structure, the first qubit in the first linear structure corresponding to the center qubit Qᵢ, and the second qubit in the second linear structure corresponding to the center qubit Qᵢ, where i is a natural number greater than or equal to 0. It can be understood that the target qubit is any qubit in the quantum chip structure.

It can be understood that, when there are many different values of n, a plurality of quantum chip structures are obtained, and there may also be a plurality of target mapping distances. At this time, one or more of the target mapping distances obtained may also be output; and further, the quantum chip structure(s) (for example, one or more) corresponding to the target mapping distance(s) may also be output. Thus, a visual structure diagram is provided, to provide the support for the subsequent preparation of the quantum chip structure(s).

Here, the sub-mapping distance is the minimum number of couplers contained in a feasible path (i.e., a passage) connecting two target qubits (for example, two target qubits in the pair of target qubits).

In one example, the pair of target qubits is an ordered target qubit pair. For the ordered target qubit pair, reference may be made to the above description, which will not be repeated here.

Thus, the solution of the present disclosure can obtain a quantum chip structure with high connectivity in the case of determining the required total number of quantum bits, to provide structural support for the subsequent design of a high-performance quantum chip.

Moreover, compared with the common quantum chip design solutions in the industry, the quantum chip structure can be implemented by a simple micro-nano processing technology. For example, only the 2D micro-nano processing technology is required to realize the quantum chip structure of the solution of the present disclosure, and the air bridge process is not used in the whole process. At the same time, the quantum chip structure also has the high connectivity.

Furthermore, since the linear structures of the solution of the present disclosure are drawn out toward the outside of the ring structure, the space layout of the obtained quantum chip structure is reasonable and the space utilization rate is large. Compared with the 2D solution in the industry scene, the solution of the present disclosure fully utilizes the entire space and leaves sufficient space to provide convenience for the subsequent arrangement of the reading resonator, reading line and control line. At the same time, the integration level of the quantum chip structure is also high. Furthermore, the solution of the present disclosure does not limit the number of center qubits, first qubits and second qubits, so the expandability is strong.

In a specific example of the solution of the present disclosure, as shown in FIG. 4, the method includes the followings.

Step S401: obtaining a total number of qubits N in a quantum chip structure to be determined; where the quantum chip structure is the quantum chip structure described above.

Step S402: determining a first value of the number of center qubits n in the ring structure of the quantum chip structure based on the total number of qubits N, where i is a natural number greater than or equal to 0 and less than or equal to n−1.

In a specific example, the first value of the number of center qubits n is one of: └\sqrt{2N}┘−1, └\sqrt{2N}┘, and └\sqrt{2N}┘+1.

That is, the first value of n may be specifically └\sqrt{2N}┘−1 or └\sqrt{2N}┘ or └\sqrt{2N}┘+1. or at least two or three thereof. Here, └\sqrt{2N}┘ represents the largest integer not greater than \sqrt{2N}. Thus, a simple and feasible value scheme of n is provided, to lay the foundation for obtaining the quantum chip structure with high connectivity.

It can be understood that the above-mentioned value of n is only a specific example, and other values may also be possible in practical applications, which are not exhaustive here and will not be limited in the solution of the present disclosure.

Step S403: determining a second value of the number of first qubits aᵢ in the first linear structure corresponding to the center qubit Qᵢ and a third value of the number of second qubits bᵢ in the second linear structure corresponding to the center qubit Qᵢ, based on the total number of qubits N and the first value.

For example, the second and third values may be obtained in the following ways.

In the first way: in the case of determining the first value of n, all possible values of aᵢ and bᵢ that conform to N=n+Σᵢ₌₀ⁿ⁻¹(aᵢ+bᵢ) are listed by the enumeration method.

In the second way: in the case of determining the first value of n, the target value a is obtained by the following formulas:

$$a = ⌈ \frac{N - n}{2 n} ⌉ , and δ = N - ( 2 a - 1 ) n .$$

Here,

$$⌈ \frac{N - n}{2 n} ⌉$$

represents the smallest integer not less than

$$\frac{N - n}{2 n} .$$

Based on the target value a obtained above, the values of aᵢ and bᵢ are determined, namely:

$${a}_{i} = \{ \begin{matrix}a , & if i \leq ⌈ \frac{δ}{2} ⌉ - 1 ; \\ a - 1 , & if i \geq ⌈ \frac{δ}{2} ⌉\end{matrix} ,$$

$${b}_{i} = \{ \begin{matrix}a , & if i \leq ⌊ \frac{δ}{2} ⌋ - 1 ; \\ a - 1 , & if i \geq ⌊ \frac{δ}{2} ⌋\end{matrix} .$$

Here,

$$⌈ \frac{δ}{2} ⌉$$

represents me smallest integer not less than

$$\frac{δ}{2} ; and ⌊ \frac{δ}{2} ⌋$$

represents the largest integer not greater than

$$\frac{δ}{2} .$$

That is to say, the target value is obtained based on the total number N of qubits and the first value n, and then the second value of the number aᵢ and the third value of the number bᵢ are obtained based on the target value.

It can be understood that the above is only exemplary description, and the three values may also be obtained in other ways, which are not exhaustive here, as long as the three values obtained conform to N=n+Σᵢ₌₀ⁿ⁻¹(aᵢ+bᵢ).

Step S404: determining a target mapping distance of the quantum chip structure based on the total number N of qubits, the first value, the second value and the third value, where the target mapping distance is determined based on a sub-mapping distance of a target qubit pair in the quantum chip structure, and the sub-mapping distance characterizes a minimum number of couplers between one target qubit of the pair of target qubits and the other target qubit of the pair of target qubits; the target qubit in the pair of target qubits is one of: a center qubit in a ring structure of the quantum chip structure, a first qubit in a first linear structure corresponding to a center qubit Qᵢ, and a second qubit in a second linear structure corresponding to the center qubit Qᵢ, where i is a natural number greater than or equal to 0.

That is to say, in this example, the first value of the number of center qubits n in the ring structure of the quantum chip structure can be obtained based on the total number of qubits N, and the second value of the number of first qubits aᵢ in the first linear structure corresponding to the center qubit Qᵢ and the third value of the number of second qubits bᵢ in the second linear structure corresponding to Qᵢ in the quantum chip structure can be obtained based on the total number of qubits N and the first value, so that the target mapping distance is obtained in the case when n, aᵢ and bᵢ are known.

In practical applications, there are many design schemes for the linear structures in the quantum chip structure, that is, when the total number of qubits N and the first value are determined, aᵢ and bᵢ in the linear structures may have different value combinations. Therefore, as the values of aᵢ and bᵢ in the linear structures vary, the quantum chip structure will vary, and the obtained target mapping distance may vary since the quantum chip structure varies. Thus, one or more target mapping distances may be output in practical applications. At this time, the one or more target mapping distances obtained may also be output; and further, the quantum chip structure(s) (for example, one or more) corresponding to the target mapping distance(s) may also be output. Thus, a visual structure diagram is provided, to provide the support for the subsequent preparation of the quantum chip structure(s).

Here, the sub-mapping distance is the minimum number of couplers contained in a feasible path (i.e., a passage) connecting two target qubits (for example, two target qubits in the pair of target qubits).

In one example, the pair of target qubits is an ordered pair of target qubits. For the ordered pair of target qubits, reference may be made to the above description, which will not be repeated here.

Thus, the solution of the present disclosure can obtain a quantum chip structure with high connectivity in the case of determining the required total number of quantum bits, to provide structural support for the subsequent design of a high-performance quantum chip.

Moreover, compared with the common quantum chip design solutions in the industry, the quantum chip structure can be implemented by a simple micro-nano processing technology. For example, only the 2D micro-nano processing technology is required to realize the quantum chip structure of the solution of the present disclosure, and the air bridge process is not used in the whole process. At the same time, the quantum chip structure also has the high connectivity.

Furthermore, since the linear structures of the solution of the present disclosure are drawn out toward the outside of the ring structure, the space layout of the obtained quantum chip structure is reasonable and the space utilization rate is large. Compared with the 2D solution in the industry scene, the solution of the present disclosure fully utilizes the entire space and leaves sufficient space to provide convenience for the subsequent arrangement of the reading resonator, reading line and control line. At the same time, the integration level of the quantum chip structure is also high. Furthermore, the solution of the present disclosure does not limit the number of center qubits, first qubits and second qubits, so the expandability is strong.

In a specific example of the solution of the present disclosure, the target mapping distance is a sum of sub-mapping distances of all pairs of target qubits (for example, ordered pairs of target qubits) in the quantum chip structure, that is, a sum of mapping distances.

Alternatively, the target mapping distance is an average value of sub-mapping distances of all pairs of target qubits (for example, different ordered pairs of target qubits) in the quantum chip structure, that is, the average mapping distance. The average mapping distance may be regarded as an average value of the mapping distances of all different ordered pairs of target qubits (that is, two target qubits in an ordered pair of target qubits are different, for example, the target qubit Qᵢ and the target qubit Qⱼ in the different ordered pair of target qubits (Qᵢ, Qⱼ) are different, i.e., i≠j). It can be understood that the average mapping distance is another indicator, which can also measure the connectivity of the quantum chip structure.

For example, the average mapping distance

$$d = \frac{D}{N ( N - 1 )} ;$$

where D is the sum of mapping distances.

Understandably, the smaller the sum of mapping distances (or the average mapping distance), the better the connectivity of the quantum chip structure. Thus, the foundation for obtaining a quantum chip structure with high connectivity is laid, and at the same time, a quantifiable solution is provided.

In a specific example of the solution of the present disclosure, the step of determining the target mapping distance of the quantum chip structure includes: using a minimum sum from a plurality of sums as the target mapping distance when the plurality of sums are determined (that is, there are a plurality of sums of mapping distances, for example, the plurality of sums of mapping distances may be determined when there are multiple values of n); or using a minimum average value from a plurality of average values as the target mapping distance when the plurality of average values are determined (that is, there are a plurality of average mapping distances, for example, the plurality of average mapping distances may be determined when there are multiple values of n). Thus, the foundation for obtaining a quantum chip structure with high connectivity is laid, and at the same time, a quantifiable solution is provided.

Thus, the solution of the present disclosure can obtain a quantum chip structure with high connectivity in the case of determining the required total number of quantum bits, to provide structural support for the subsequent design of a high-performance quantum chip.

Moreover, compared with the common quantum chip design solutions in the industry, the quantum chip structure can be implemented by a simple micro-nano processing technology. For example, only the 2D micro-nano processing technology is required to realize the quantum chip structure of the solution of the present disclosure, and the air bridge process is not used in the whole process. At the same time, the quantum chip structure also has the high connectivity.

Furthermore, since the linear structures of the solution of the present disclosure are drawn out toward the outside of the ring structure, the space layout of the obtained quantum chip structure is reasonable and the space utilization rate is large. Compared with the 2D solution in the industry scene, the solution of the present disclosure fully utilizes the entire space and leaves sufficient space to provide convenience for the subsequent arrangement of the reading resonator, reading line and control line. At the same time, the integration level of the quantum chip structure is also high. Furthermore, the solution of the present disclosure does not limit the number of center qubits, first qubits and second qubits, so the expandability is strong.

The solution of the present disclosure will be further described in detail below with reference to specific examples, and specifically, the solution of the present disclosure will be described from four parts. The first part mainly introduces the quantum chip structure of the solution of the present disclosure; the second part explains the scheme of efficiently obtaining a quantum chip structure with strong connectivity given the specific total number of qubits; the third part gives a wiring example based on the solution of the present disclosure, to illustrate that the design of other devices and connection lines can be well completed using the solution of the present disclosure, and the air bridge technology is not required; and the fourth part shows the connectivity feature of the solution of the present disclosure, and compares it with several common design solutions in the industry to verify the advantages of the solution of the present disclosure.

The first part: the quantum chip structure of the solution of the present disclosure; and specifically, the solution of the present disclosure provides a novel design solution of the quantum chip structure.

The core content of the quantum chip structure of the solution of the present disclosure is introduced in detail with reference to the example of FIG. 1. As shown in FIG. 1, the dots represent qubits. For example, in an example, the qubits may be specifically computing qubits (i.e., qubits for computation), that is, the dots in FIG. 1 represent computing qubits; and the solid lines represent couplers (which are usually implemented by qubits, and of which the core function is to regulate the coupling strength between two connected qubits).

Further, as shown in FIG. 1, the layout of core devices (including qubits and couplers) in the quantum chip structure of the present disclosure is as follows.

A ring structure containing n (n is a natural number greater than or equal to 3) qubits (that is, center qubits) is arranged in the center of the quantum chip structure; and in the ring structure, every two qubits (that is, every two center qubits) are connected through a coupler (a solid line shown in FIG. 1).

A two-linear structure is drawn from a center qubit Qᵢ (i=0, 1, 2, . . . , n−1) in the ring structure toward the outside of the ring structure, where a first linear structure in the two-linear structure contains aᵢ qubits (i.e., first qubits); and a second linear structure in the two-linear structure contains bᵢ qubits (i.e., second qubits); where aᵢ and bᵢ are natural numbers greater than or equal to 1.

Here, two adjacent first qubits in the first linear structure in the two-linear structure are connected to each other through a coupler; and similarly, two adjacent second qubits in the second linear structure in the two-linear structures are connected to each other through a coupler. Moreover, a first qubit adjacent to the center qubit Qᵢ in the first linear structure is connected to the center qubit Qᵢ through a coupler; and a second qubit adjacent to the center qubit Qᵢ in the second linear structure is connected to the center qubit Qᵢ through a coupler.

Based on this, the total number of qubits (i.e., center qubits, first qubits and second qubits) contained in the quantum chip structure is N=n+Σᵢ₌₀ⁿ⁻¹(aᵢ+bᵢ).

It can be understood that, in the solution of the present disclosure, since any two adjacent qubits are connected through a coupler, the total number of couplers contained in the quantum chip structure is equal to the total number of qubits contained.

Furthermore, it can be understood that the dotted lines shown in FIG. 1 indicate that several qubits and couplers are omitted. Specifically, the dotted lines in the ring structure indicate that several center qubits and couplers for connecting two adjacent center qubits are omitted; and similarly, the dotted lines in the first linear structure indicate that several first qubits and couplers for connecting two adjacent first qubits are omitted; and the dotted lines in the second linear structure indicate that several second qubits and couplers for connecting two adjacent second qubits are omitted.

Here, in order to more vividly show and present the layout of the qubits (including the center qubits, the first qubits and the second qubits) in the quantum chip structure, two groups of (n, aᵢ, bᵢ) with different values are listed below to illustrate as examples. The examples specifically include the followings.

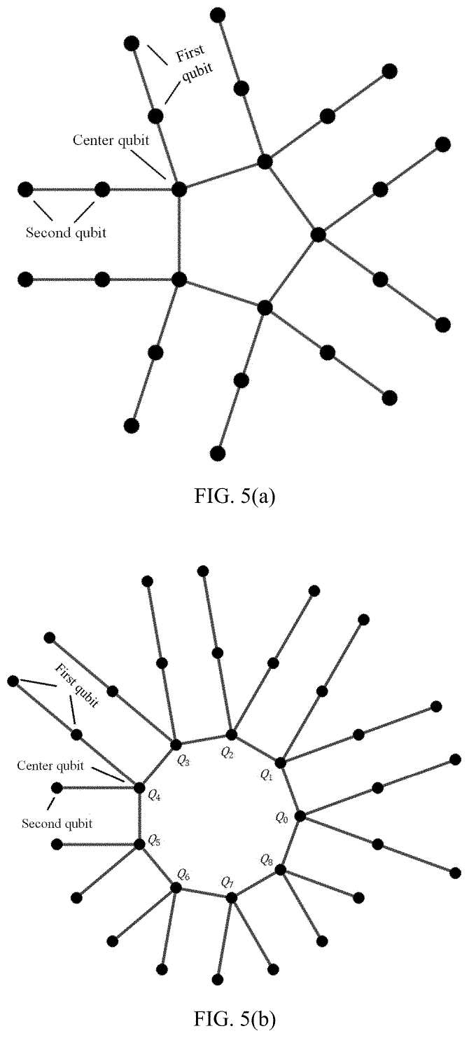

Example 1: as shown in FIG. 5(a), n=5, aᵢ=2, bᵢ=2, and at this time, the total number N of qubits (including center qubits, first qubits and second qubits) contained in the quantum chip structure described in this example is 25, while the number of couplers in the quantum chip structure in this example is also 25.

Example 2: as shown in FIG. 5(b), n=9, aᵢ=2 when i≤4; aᵢ=1 when i≥5; bᵢ=2 when i≤3, and bᵢ=1 when i≥4; specifically, the number of first qubits corresponding to each of the center qubit Q₀, the center qubit Q₁, the center qubit Q₂ and the center qubit Q₃ is 2, and the number of second qubits corresponding to each of the center qubit Q₀, the center qubit Q₁, the center qubit Q₂ and the center qubit Q₃ is also 2; the number of first qubits corresponding to the center qubit Q₄ is 2, and the number of second qubits corresponding to the center qubit Q₄ is 1; and the number of first qubits corresponding to each of the center qubit Q₅, the center qubit Q₆, the center qubit Q₇ and the center qubit Q₈ is 1, and the number of second qubits corresponding to each of the center qubit Q₅, the center qubit Q₆, the center qubit Q₇ and the center qubit Q₈ is 1. The total number N of qubits (including center qubits, first qubits and second qubits) contained in the quantum chip structure described in this example is 36, while the number of couplers in the quantum chip structure in this example is also 36.

It can be understood that FIG. 5(a) and FIG. 5(b) are only exemplary descriptions. In practical applications, (n, aᵢ, bᵢ) are also other natural numbers, which are not exhaustive here and will not be limited in the solution of the present disclosure.

In this way, the quantum chip structure described in the solution of the present disclosure can complete the micro-nano processing by using only the 2D micro-nano processing technology without using the air bridge technology, and a quantum chip with the quantum chip structure is prepared. Moreover, compared with many design solutions in the industry, the quantum chip structure described in the solution of the present disclosure or the quantum chip prepared based on the quantum chip structure of the solution of the present disclosure has the stronger qubit connectivity.

Moreover, since the quantum chip structure of the solution of the present disclosure forms the ring structure in the center area and expands from the center qubits in the center area to the outside of the ring structure, the space utilization rate is higher and the space layout is more reasonable, to provide convenience for the subsequent arrangement of the reading resonator, reading line and control line; and at the same time, the overall integration is higher; and furthermore, since the solution of the present disclosure does not limit the number of center qubits, first qubits and second qubits, the solution of the present disclosure has the strong expansibility.

The second part: given the specific number of qubits N, a quantum chip structure with high connectivity is efficiently obtained.

Specifically, the given total number of qubits N is the design requirement, and the solution of the present disclosure can provide a determining solution to determine a set of parameter values, that is, the specific values of parameters (n, aᵢ, bᵢ), to thereby determine the quantum chip structure. As discussed above, once (n, aᵢ, bᵢ) are determined, the entire quantum chip structure is determined.

Before the specific solution is introduced, a concept related to the structural connectivity of the quantum chip-mapping distance (that is, the sub-mapping distance described above) is introduced. The “mapping distance” of two target qubits in the quantum chip structure refers to the minimum number of couplers contained in a feasible path (i.e., a passage) connecting the two target qubits; and correspondingly, the sum of the mapping distances of the quantum chip structure is the sum of the mapping distances (i.e., sub-mapping distances) of all ordered pairs of target qubits. Here, the smaller the sum of the mapping distances, the better the connectivity of the quantum chip structure.

Here, the feasible path refers to a path with solid lines (i.e., couplers) in the quantum chip structure. For example, as shown in FIG. 5(b), the number of couplers contained in the feasible path between the first center qubit Q₁ and the fifth center qubit Q₅ is 4 or 5. The minimum number of couplers contained in the feasible path is 4, that is, the mapping distance (i.e., the sub-mapping distance) between the first center qubit Q₁ and the fifth center qubit Q₅ is 4.

Further, the specific determining solution is as follows.

Step 501: inputting the total number of qubits N (including center qubits, first qubits and second qubits) in the quantum chip structure, and determining the numerical value (i.e., a first value) of the number of qubits n (i.e., center qubits) in the ring structure of the quantum chip structure.

For example, the value of n may be specifically └\sqrt{2N}┘−1or └\sqrt{2N}┘ or └\sqrt{2N}┘+1. where └\sqrt{2N}┘ represents the largest integer not greater than \sqrt{2N}.

It can be understood that the above-mentioned value of n is only a specific example, and other values may also be possible in practical applications, which are not exhaustive here and will not be limited in the solution of the present disclosure.

Step 502: calculating the values of aᵢ and bᵢ when the value of n is determined.

For example, they may be obtained in the following ways.

In the first way: all possible values of aᵢ and bᵢ that conform to N=n+Σᵢ₌₀ⁿ⁻¹(aᵢ+bᵢ) are listed by the enumeration method.

In the second way: the target value a is obtained by the following formula:

$$a = ⌈ \frac{N - n}{2 n} ⌉ ,$$

$$and δ = N - ( 2 a - 1 ) n .$$

Here,

$$⌈ \frac{N - n}{2 n} ⌉$$

represents the smallest integer not less than

$$\frac{N - n}{2 n} .$$

Based on the target value a obtained above, the values of aᵢ and bᵢ are determined, namely:

$${a}_{i} = \{ \begin{matrix}a , & if i \leq ⌈ \frac{δ}{2} ⌉ - 1 ; \\ a - 1 , & if i \geq ⌈ \frac{δ}{2} ⌉\end{matrix} ,$$

$${b}_{i} = \{ \begin{matrix}a , & if i \leq ⌊ \frac{δ}{2} ⌋ - 1 ; \\ a - 1 , & if i \geq ⌊ \frac{δ}{2} ⌋\end{matrix} .$$

Here,

$$⌈ \frac{δ}{2} ⌉$$

represents the smallest integer not less than

$$\frac{δ}{2} ; and ⌊ \frac{δ}{2} ⌋$$

represents the largest integer not greater than

$$\frac{δ}{2} .$$

Step 503: determining the sum D of mapping distances based on the following formula when n, aᵢ, and bᵢ are all known. The physical image corresponding to the sum of the mapping distances is the sum of the number of couplers on the shortest path (that is, the path containing the minimum number of couplers) among all the ordered pairs of qubits (that is, the pairs of target qubits). The specific formula is as follows:

$$D = {\sum }_{i = 0}^{n - 1} {\sum }_{j = 0}^{n - 1} {\sum }_{k = - {b}_{i}}^{{a}_{i}} {\sum }_{l = - {b}_{j}}^{{a}_{j}} \vert k \vert + \vert l \vert + min ( n - \vert i - j \vert , \vert i - j \vert ) + {\sum }_{i = 0}^{n - 1} {\sum }_{k = - {b}_{i}}^{{a}_{i}} {\sum }_{l = - {b}_{j}}^{{a}_{j}} \vert k - l \vert - \vert k \vert - \vert l \vert ,$$

where i, j, k and l represent indicators of different qubits, min(n−|i−j|, |i−j|) represents the minimum of n−|i−j| and |i−j|; |k−l| represents the absolute value of k−l; |k| represents the absolute value of k; and |l| represents the absolute value of l.

Step 504: outputting the sum of mapping distances.

It can be understood that the obtained sum of mapping distances may vary when the value of n varies, so the sum of mapping distances output in step 504 may have a plurality of values. For example, for this example, n has three values, so the output sum of mapping distances has three values. Alternatively, in an example, the minimum of three values of the sum of mapping distances may also be used as the final output result.

The above determining process is demonstrated below by taking N=36 as an example, specifically including the followings.

Step 601: determining n=7 or 8 or 9.

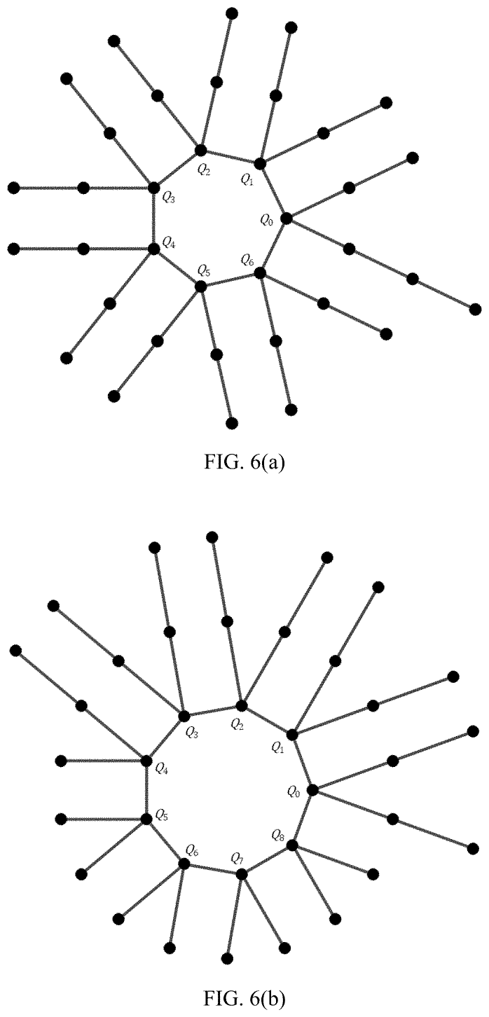

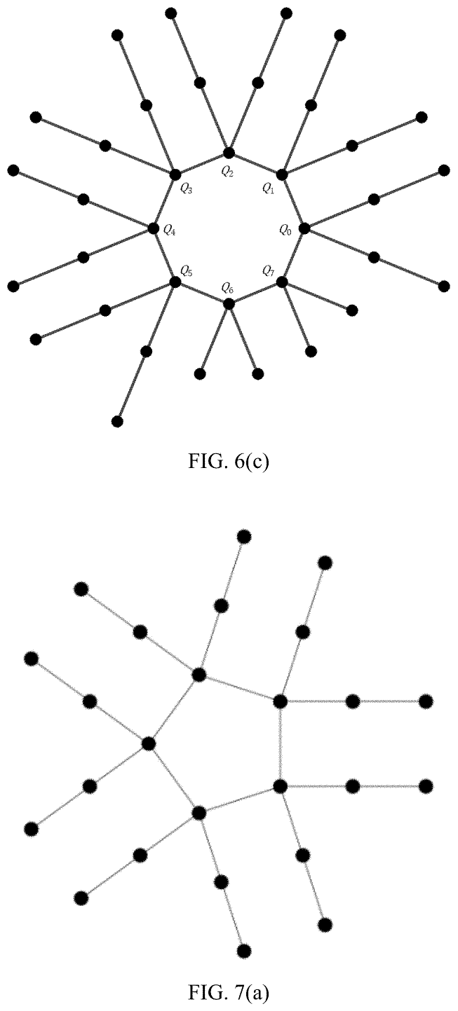

Step 602: calculating the values of aᵢ and bᵢ when the value of n is determined. For example, for (N=36, n=7), the values of aᵢ and bᵢ are obtained, and the quantum chip structure shown in FIG. 6(a) is obtained; for (N=36, n=8), the values of aᵢ and bᵢ are obtained, and the quantum chip structure shown in FIG. 6(b) is obtained; for (N=36, n=9), the values of aᵢ and bᵢ are obtained, and the quantum chip structure shown in FIG. 6(c) is obtained.

Step 603: calculating the sums of mapping distances corresponding to the quantum chip structures shown in FIG. 6(a), FIG. 6(b) and FIG. 6(c), which are 5302, 5320 and 5304 respectively.

Step 604: outputting the minimum sum 5302 of mapping distances. At the same time, the minimum value 5302 may also be output.

The quantum chip structure shown in FIG. 6(a) has the strongest connectivity.

It can be understood that a visualization diagram as shown in FIG. 6(a) may also be output, thus facilitating to view and improving the user experience.

The solution of the present disclosure shows a relationship between the number n of center qubits of the ring structure and the input total number N of qubits in the above solution, as follows.

Relationship between the number n of center qubits and the total number N of qubits

| N | n |
|---|---|
| 3~9 | 3 |
| 10~11 | 5 |
| 12 | 4 |
| 13~17 | 5 |
| 18~19 | 6 |
| 20~36 | 7 |
| 37~38 | 9 |
| 39~40 | 8 |
| 41~48 | 9 |
| 49~52 | 10 |
| 53~78 | 11 |
| 79~81 | 13 |
| 82~84 | 12 |
| 85~95 | 13 |
| 96~101 | 14 |
| 102~137 | 15 |
| 138~139 | 17 |
| 140~145 | 16 |
| 146~159 | 17 |
| 160~166 | 18 |
| 167~212 | 19 |
| 213~214 | 21 |
| 215~221 | 20 |
| 222~238 | 21 |
| 239~247 | 22 |
| 248~303 | 23 |
| 304 | 25 |
| 305~313 | 24 |

It can be understood that the above values of N and n are only exemplary and are not used to limit the solution of the present disclosure. In practical applications, there may be other value relationships, which are not limited in the solution of the present disclosure.

Moreover, in practical applications, when the number n is relatively small, there may be a situation where the number of qubits in a linear structure corresponding to a center qubit is 0.

It is worth noting that it is reasonable to use the sum of mapping distances as a measure of the pros and cons of the solution, because: when a quantum chip (or superconducting quantum chip) executes a specific quantum algorithm, the concept of the sum of mapping distances needs to be introduced to compensate for the defect of inability to act a two-bit quantum gate (that is, two-qubit gate) on any two qubits. Moreover, especially for a random quantum circuit, the cost of using the sum of mapping distances is much less than the cost of the mapping algorithm. In practical applications, the cost of the mapping algorithm may be approximately considered to be proportional to the sum of mapping distances.

The third part: the wiring shows that there is no need to introduce the air bridge technology.

The quantum chip structure proposed in the solution of the present disclosure can be realized by using the 2D micro-nano processing technology. This part will demonstrate by way of examples that the subsequent read resonator design (for reading the information of qubits), read line design (usually a plurality of qubits share one read line) and control line design (for controlling the qubits or coupled devices to perform the corresponding operations) may be well completed based on this solution, and the air bridge process is not used in the whole process.

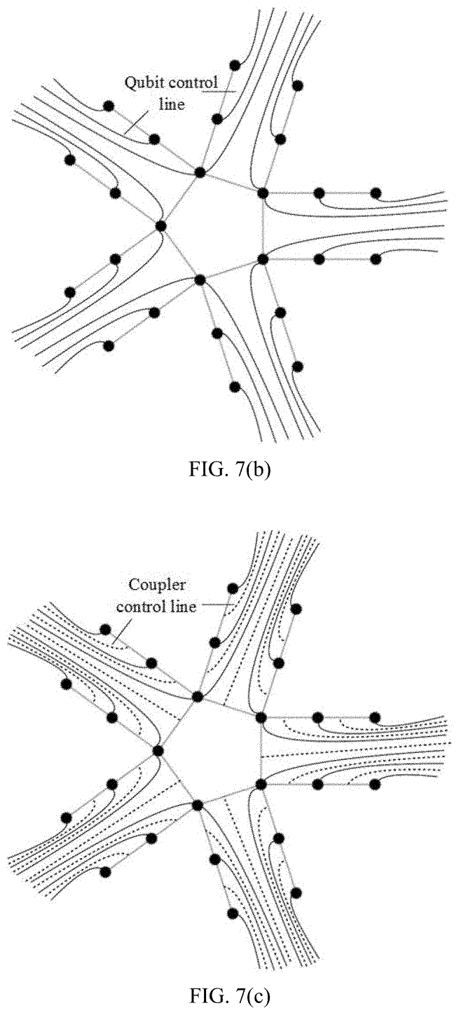

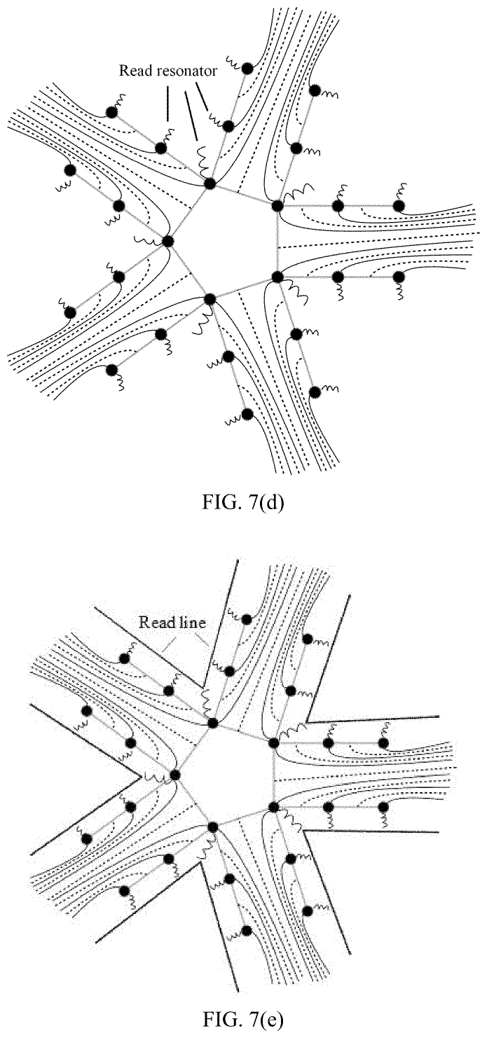

Taking N=25 and n=5 (that is, the total number of qubits in the quantum chip structure is 25, and the number of center qubits is 5) as an example, the complete wiring scheme and its process will be shown with reference to FIGS. 7(a) to 7(e).

It can be understood that the wiring process is performed on a basis of obtaining the quantum chip structure shown in FIG. 7(a). Specifically, the wiring process includes the followings.

Step 1: arranging the qubit control lines. As shown in FIG. 7(b), each qubit (including the center qubit, the first qubit, and the second qubit) leads out a qubit control line. It can be understood that two qubit control lines may be leaded out, of which one is used to control the XY channel and the other is used to control the Z channel. In practical applications, the qubit control lines may be set based on requirements, which is not limited in the solution of the present disclosure.

Step 2: arranging the coupler control lines. As shown in FIG. 7(c), each coupler leads out a control line (that is, the dotted line in FIG. 7(c)), which is usually used to control the Z channel.

Step 3: adding the read resonators. As shown in FIG. 7(d), each qubit (including the center qubit, the first qubit and the second qubit) is coupled with one read resonator (i.e., the serpentine line in FIG. 7(d)).

Step 4: arranging the read lines. For example, as shown in FIG. 7(e), every five (other value is also possible in practical applications, and this value is not specifically limited in the solution of the present disclosure) read resonators share one read line (the V-shaped line in FIG. 7(e)).

It can be clearly seen from FIGS. 7(a) to 7(e) that there is no intersection between any two lines, including two read lines, a read line and a control line (qubit control line or coupler control line), and two control lines. This fully proves that the quantum chip structure of the solution of the present disclosure can be realized without using the air bridge micro-nano processing technology.

It can be understood that (n=5, aᵢ=2, bᵢ=2) is only taken as an example for description in FIGS. 7(a) to 7(e). For other values of (n, aᵢ, bᵢ), there are still all the advantages described in the solution in the present disclosure, which are not exhaustive in the solution of the present disclosure. Those values fall into the protection scope of the solution of the present disclosure as long as they meet the structure requirements described in the solution of the present disclosure.

The fourth part: the advantages of performance indicators of the connectivity are shown.

The advantages of the solution of the present disclosure in connectivity are shown below. Here, with the connectivity as a performance indicator, the solution of the present disclosure is compared with three commonly used solutions in the industry.

As mentioned above, an indicator to measure the connectivity of a quantum chip structure (or quantum chip) may be the sum of mapping distances. For a superconducting quantum chip structure, this example defines the mapping distance (that is, the sub-mapping distance) between any two qubits as follows: traverse the couplers contained in all possible feasible paths which start and end with the two qubits respectively in the quantum chip structure, obtain the numbers of couplers contained in all the feasible paths which start and end with the two qubits, and define the minimum of the numbers of couplers contained as the mapping distance between the two qubits. Here, the mapping distance from a qubit to itself is 0. Accordingly, the sum of mapping distances is the sum of mapping distances of all possible ordered qubit pairs. Moreover, the smaller the sum of mapping distances, the smaller the cost of using the mapping algorithm by the quantum chip structure, and the better the connectivity performance accordingly.

Here, in order to better demonstrate the connectivity performance under different numbers of qubits, the solution of the present disclosure introduces another connectivity indicator, that is, the average mapping distance

$$d = \frac{D}{N ( N - 1 )} ,$$

which may be regarded as an average value of the mapping distances of all different qubit pairs (that is, two qubits in a qubit pair are different, for example, the qubit Qᵢ and the qubit Qᵢ in the different qubit pair (Qᵢ, Qⱼ) are different). It can be understood that the average mapping distance is another indicator, which can also measure the connectivity of the quantum chip structure.

There are three design solutions commonly used in the industry.

Solution 1: an one-dimensional chain chip containing 9 qubits, prepared by the 2D micro-nano process.

Solution 2: a “regular octagon+regular quadrangle” densely-laid chip containing 80 qubits, prepared by the 3D micro-nano processing technology.

Solution 3: a “heavy hexagon” densely-laid chip containing 127 qubits, prepared by the 3D micro-nano processing technology.

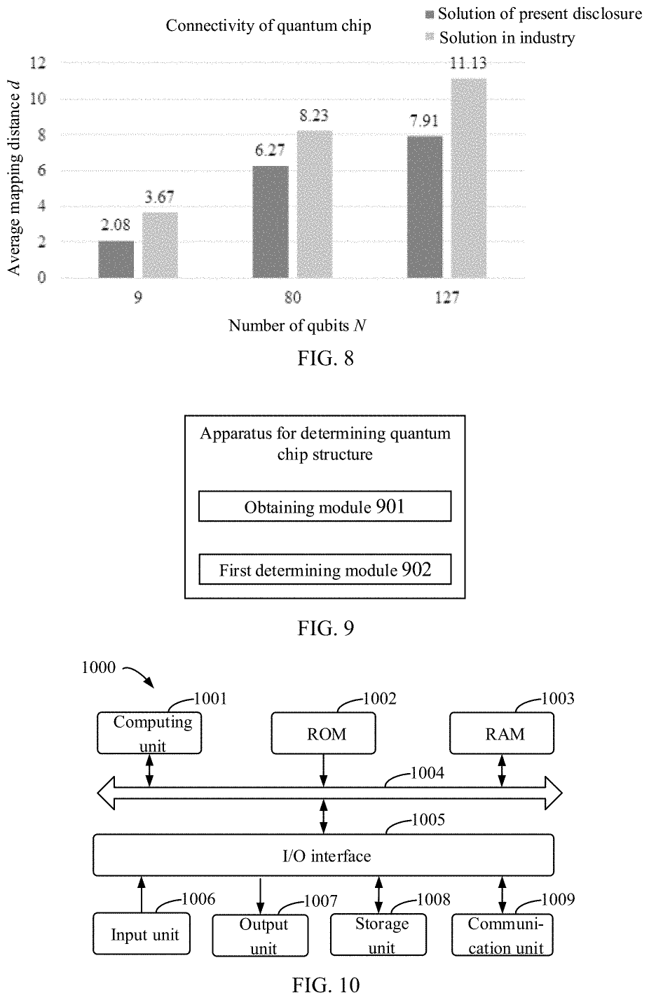

As shown in FIG. 8, compared with the 2D solution (i.e., solution 1) in the industry, the solution of the present invention presents a significant advantage in connectivity. It is worth noting in particular that the solution of the present invention is even better than some 3D solutions (i.e., solutions 2 and 3) in the industry in terms of connectivity.
1. The micro-nano processing technology is relatively simple; the solution of the present disclosure only needs the 2D micro-nano processing technology to complete the quantum chip structure described in the solution of the present disclosure, and there is no need to use the air bridge process in the entire process.
2. The qubits have the strong connectivity. Compared with the structure of the existing 2D micro-nano process, the quantum chip structure provided in the solution of the present disclosure has the strong connectivity. Moreover, benefiting from the strong connectivity, the solution of the present disclosure can provide structural support for designing the high-performance quantum chip. It can be found from further analysis that the connectivity of the quantum chip structure of the solution of the present disclosure is even better than some 3D solutions in the industry.
3. The space layout is more reasonable and the space utilization rate is greater. Compared with the common 2D solution in the industry, the solution of the present disclosure fully utilizes the entire space, and leaves sufficient space for the subsequent design of the read resonator, reading line and control line; and the overall integration is higher.
4. The expansibility is strong. The solution of the present disclosure is not limited to a specific design solution, but a series of design solutions with similar structures. After calculation, it can be seen that the quantum chip structure of the solution of the present disclosure still has the excellent connectivity even if it is extended to thousands of qubits.

The solution of the present disclosure also provides a determining apparatus, as shown in FIG. 9, including: an obtaining module 901 configured to obtain a total number N of qubits in a quantum chip structure to be determined; where the quantum chip structure is the quantum chip structure described above; and a first determining module 902 configured to determine a target mapping distance of the quantum chip structure based on at least the total number of qubits N, where the target mapping distance is determined based on a sub-mapping distance of a target qubit pair in the quantum chip structure, and the sub-mapping distance characterizes a minimum number of couplers between one target qubit of the pair of target qubits and the other target qubit of the pair of target qubits; the target qubit in the target qubit pair is one of: the center qubit in a ring structure of the quantum chip structure, the first qubit in the first linear structure corresponding to the center qubit Qᵢ, and the second qubit in the second linear structure corresponding to the center qubit Qᵢ, where i is a natural number greater than or equal to 0.

In a specific example of the solution of the present disclosure, the pair of target qubits is an ordered pair of target qubits.

In a specific example of the solution of the present disclosure, the apparatus further includes: a second determining module configured to determine a first value of the number of center qubits n in the ring structure of the quantum chip structure based on the total number of qubits N, where i is a natural number greater than or equal to 0 and less than or equal to n−1; and the first determining module is specifically configured to determine the target mapping distance of the quantum chip structure based on the total number of qubits N and the first value.

In a specific example of the solution of the present disclosure, the apparatus further includes: a third determining module configured to determine a second value of the number of first qubits aᵢ in the first linear structure corresponding to the center qubit Qᵢ and a third value of the number of second qubits bᵢ in the second linear structure corresponding to the center qubit Qᵢ, based on the total number of qubits N and the first value; and the first determining module is specifically configured to determine the target mapping distance of the quantum chip structure based on the total number of qubits N, the first value, the second value and the third value.

In a specific example of the solution of the present disclosure, the first value of the number of center qubits n is one of: └\sqrt{2N}┘−1, └\sqrt{2N}┘, and └\sqrt{2N}┘+1.

In a specific example of the solution of the present disclosure, the target mapping distance is a sum of sub-mapping distances of all the target qubit pairs in the quantum chip structure; or the target mapping distance is an average value of sub-mapping distances of all pairs of target qubits in the quantum chip structure.

In a specific example of the solution of the present disclosure, the first determining module is specifically configured to: use a minimum sum from a plurality of sums as the target mapping distance when the plurality of sums are determined; or use a minimum average value from a plurality of average values as the target mapping distance when the plurality of average values are determined.

Here, the functions of the modules in the apparatus may refer to the above solution, and details are not repeated here.

The solution of the present disclosure also provides a quantum chip with the quantum chip structure described above.

The solution of the present disclosure also provides a quantum computer, including the quantum chip described above, and an external control system connected with the quantum chip.

According to the embodiments of the present disclosure, the present disclosure also provides an electronic device, a readable storage medium and a computer program product.

FIG. 10 shows a schematic block diagram of an exemplary electronic device 1000 that may be used to implement the embodiments of the present disclosure. The electronic device is intended to represent various forms of digital computers, such as a laptop, a desktop, a workstation, a personal digital assistant, a server, a blade server, a mainframe computer, and other suitable computers. The electronic device may also represent various forms of mobile devices, such as a personal digital processing, a cellular phone, a smart phone, a wearable device and other similar computing devices. The components shown herein, their connections and relationships, and their functions are merely examples, and are not intended to limit the implementation of the present disclosure described and/or required herein.

As shown in FIG. 10, the device 1000 includes a computing unit 1001 that may perform various appropriate actions and processes according to a computer program stored in a Read-Only Memory (ROM) 1002 or a computer program loaded from a storage unit 1008 into a Random Access Memory (RAM) 1003. Various programs and data required for an operation of device 1000 may also be stored in the RAM 1003. The computing unit 1001, the ROM 1002 and the RAM 1003 are connected to each other through a bus 1004. The input/output (I/O) interface 1005 is also connected to the bus 1004.

A plurality of components in the device 1000 are connected to the I/O interface 1005, and include an input unit 1006 such as a keyboard, a mouse, or the like; an output unit 1007 such as various types of displays, speakers, or the like; the storage unit 1008 such as a magnetic disk, an optical disk, or the like; and a communication unit 1009 such as a network card, a modem, a wireless communication transceiver, or the like. The communication unit 1009 allows the device 1000 to exchange information/data with other devices through a computer network such as the Internet and/or various telecommunication networks.

The computing unit 1001 may be various general-purpose and/or special-purpose processing components with processing and computing capabilities. Some examples of the computing unit 1001 include, but are not limited to, a Central Processing Unit (CPU), a Graphics Processing Unit (GPU), various dedicated Artificial Intelligence (AI) computing chips, various computing units that run machine learning model algorithms, a Digital Signal Processor (DSP), and any appropriate processors, controllers, microcontrollers, or the like. The computing unit 1001 performs various methods and processing described above, such as the determining method. For example, in some implementations, the determining method may be implemented as a computer software program tangibly contained in a computer-readable medium, such as the storage unit 1008. In some implementations, a part or all of the computer program may be loaded and/or installed on the device 1000 via the ROM 1002 and/or the communication unit 1009. When the computer program is loaded into RAM 1003 and executed by the computing unit 1001, one or more steps of the determining method described above may be performed. Alternatively, in other implementations, the computing unit 1001 may be configured to perform the determining method by any other suitable means (e.g., by means of firmware).

Various implementations of the system and technologies described above herein may be implemented in a digital electronic circuit system, an integrated circuit system, a Field Programmable Gate Array (FPGA), an Application Specific Integrated Circuit (ASIC), Application Specific Standard Parts (ASSP), a System on Chip (SOC), a Complex Programmable Logic Device (CPLD), a computer hardware, firmware, software, and/or a combination thereof. These various implementations may be implemented in one or more computer programs, and the one or more computer programs may be executed and/or interpreted on a programmable system including at least one programmable processor. The programmable processor may be a special-purpose or general-purpose programmable processor, may receive data and instructions from a storage system, at least one input device, and at least one output device, and transmit the data and the instructions to the storage system, the at least one input device, and the at least one output device.

The program code for implementing the method of the present disclosure may be written in any combination of one or more programming languages. The program code may be provided to a processor or controller of a general-purpose computer, a special-purpose computer or other programmable data processing devices, which enables the program code, when executed by the processor or controller, to cause the function/operation specified in the flowchart and/or block diagram to be implemented. The program code may be completely executed on a machine, partially executed on the machine, partially executed on the machine as a separate software package and partially executed on a remote machine, or completely executed on the remote machine or a server.

In the context of the present disclosure, a machine-readable medium may be a tangible medium, which may contain or store a procedure for use by or in connection with an instruction execution system, device or apparatus. The machine-readable medium may be a machine-readable signal medium or a machine-readable storage medium. The machine-readable medium may include, but is not limited to, an electronic, magnetic, optical, electromagnetic, infrared or semiconductor system, device or apparatus, or any suitable combination thereof. More specific examples of the machine-readable storage medium may include electrical connections based on one or more lines, a portable computer disk, a hard disk, a Random Access Memory (RAM), a Read-Only Memory (ROM), an Erasable Programmable Read-Only Memory (EPROM or a flash memory), an optical fiber, a portable Compact Disc Read-Only Memory (CD-ROM), an optical storage device, a magnetic storage device, or any suitable combination thereof.

In order to provide interaction with a user, the system and technologies described herein may be implemented on a computer that has: a display apparatus (e.g., a cathode ray tube (CRT) or a Liquid Crystal Display (LCD) monitor) for displaying information to the user; and a keyboard and a pointing device (e.g., a mouse or a trackball) through which the user may provide input to the computer. Other types of devices may also be used to provide interaction with the user. For example, feedback provided to the user may be any form of sensory feedback (e.g., visual feedback, auditory feedback, or tactile feedback), and the input from the user may be received in any form (including an acoustic input, a voice input, or a tactile input).

The system and technologies described herein may be implemented in a computing system (which serves as, for example, a data server) including a back-end component, or in a computing system (which serves as, for example, an application server) including a middleware, or in a computing system including a front-end component (e.g., a user computer with a graphical user interface or web browser through which the user may interact with the implementation of the system and technologies described herein), or in a computing system including any combination of the back-end component, the middleware component, or the front-end component. The components of the system may be connected to each other through any form or kind of digital data communication (e.g., a communication network). Examples of the communication network include a Local Area Network (LAN), a Wide Area Network (WAN), and the Internet.

A computer system may include a client and a server. The client and server are generally far away from each other and usually interact with each other through a communication network. A relationship between the client and the server is generated by computer programs running on corresponding computers and having a client-server relationship with each other. The server may be a cloud server, a distributed system server, or a blockchain server.

It should be understood that, the steps may be reordered, added or removed by using the various forms of the flows described above. For example, the steps recorded in the present disclosure can be performed in parallel, in sequence, or in different orders, as long as a desired result of the technical scheme disclosed in the present disclosure can be realized, which is not limited herein.

The foregoing specific implementations do not constitute a limitation on the protection scope of the present disclosure. Those having ordinary skill in the art should understand that, various modifications, combinations, sub-combinations and substitutions may be made according to a design requirement and other factors. Any modification, equivalent replacement, improvement or the like made within the spirit and principle of the present disclosure shall be included in the protection scope of the present disclosure.

What is claimed is:

1. A quantum chip structure, comprising:
a ring structure composed of n center qubits, wherein two adjacent center qubits in the ring structure are connected to each other through a coupler, and n is a natural number greater than or equal to 3; and
a two-linear structure drawn from each of the center qubits Qᵢ toward outside of the ring structure, wherein a first linear structure of the two-linear structure comprises aᵢ first qubits, and a second linear structure of the two-linear structure comprises bᵢ second qubits, and wherein aᵢ is a natural number greater than or equal to 1, bᵢ is a natural number greater than or equal to 1, and i is a natural number greater than or equal to 0 and less than or equal to n−1.

2. The quantum chip structure of claim 1, wherein
a first qubit of the first linear structure that is adjacent to the center qubit Qᵢ is connected to the center qubit Qᵢ through a coupler; and/or
a second qubit of the second linear structure that is adjacent to the center qubit Qᵢ is connected to the center qubit Qᵢ through a coupler.

3. The quantum chip structure of claim 1, wherein
in a case of there are two or more of the first qubits in the first linear structure, two adjacent first qubits are connected to each other through a coupler; and/or
in a case of there are two or more of the second qubits in the second linear structure, two adjacent second qubits are connected to each other through a coupler.

4. The quantum chip structure of claim 1, wherein the ring structure is a convex polygon, the center qubit Qᵢ is a vertex of the convex polygon, and the coupler connecting the two adjacent center qubits is a side of the convex polygon.

5. The quantum chip structure of claim 4, wherein the convex polygon is a regular polygon.

6. The quantum chip structure of claim 1, wherein two-linear structures drawn from different center qubits do not intersect.

7. The quantum chip structure of claim 1, wherein
the number of the first qubits aᵢ in the first linear structure drawn from the center qubit Qᵢ is same as the number of the second qubits bᵢ in the second linear structure drawn from the center qubit Qᵢ; or
a difference between the number of the first qubits aᵢ in the first linear structure drawn from the center qubit Qᵢ and the number of the second qubits bᵢ in the second linear structure drawn from the center qubit Qᵢ is less than or equal to a preset threshold.

8. The quantum chip structure of claim 1, further comprising:
a qubit control line configured to connect a target qubit with an external control system, wherein the target qubit is one of: the center qubit, the first qubit and the second qubit;
a coupler control line configured to connect the coupler with the external control system; and
a read resonator configured to be coupled with the target qubit;
wherein the quantum chip structure of claim 8, further comprises: a read line configured to connect a plurality of the read resonators.

9. The quantum chip structure of claim 1, wherein the center qubit is a computing qubit.

10. The quantum chip structure of claim 1, wherein the first qubit is a computing qubit, and/or the second qubit is a computing qubit.

11. The quantum chip structure of claim 1, wherein at least one of the center qubit, the first qubit and the second qubit is a superconducting qubit.

12. A determining method, comprising:
obtaining a total number of qubits N in the quantum chip structure of claim 1 to be determined; and
determining a target mapping distance of the quantum chip structure at least based on the total number of qubits N, wherein the target mapping distance is determined based on a sub-mapping distance of a pair of target qubits in the quantum chip structure, and the sub-mapping distance represents a minimum number of the couplers between one target qubit of the pair of target qubits and the other target qubit of the pair of target qubits, and wherein the target qubit of the pair of target qubits is one of: the center qubit in the ring structure of the quantum chip structure, the first qubit in the first linear structure corresponding to the center qubit Qᵢ, and the second qubit in the second linear structure corresponding to the center qubit Qᵢ, wherein i is a natural number greater than or equal to 0.

13. The method of claim 12, wherein the pair of target qubits is an ordered pair of target qubits.

14. The method of claim 12, further comprising:
determining a first value of the number of center qubits n in the ring structure of the quantum chip structure, based on the total number of qubits N, wherein i is a natural number greater than or equal to 0 and less than or equal to n−1;
wherein determining the target mapping distance of the quantum chip structure at least based on the total number of qubits N comprises:
determining the target mapping distance of the quantum chip structure based on the total number of qubits N and the first value.

15. The method of claim 14, further comprising:
determining a second value of the number of first qubits aᵢ in the first linear structure corresponding to the center qubit Qᵢ and a third value of the number of second qubits bᵢ in the second linear structure corresponding to the center qubit Qᵢ, based on the total number of qubits N and the first value;
determining the target mapping distance of the quantum chip structure based on the total number of qubits N and the first value comprises:
determining the target mapping distance of the quantum chip structure based on the total number of qubits N, the first value, the second value and the third value.

16. The method of claim 12, wherein the first value of the number of center qubits n is one of:
└\sqrt{2N}┘−1, └\sqrt{2N}┘, and └\sqrt{2N}┘+1.

17. The method of claim 12, wherein
the target mapping distance is a sum of the sub-mapping distances of all pairs of target qubits in the quantum chip structure; or
the target mapping distance is an average value of the sub-mapping distances of all pairs of target qubits in the quantum chip structure.

18. The method of claim 17, wherein determining the target mapping distance of the quantum chip structure comprises:
in a case of a plurality of sums are determined, using a minimum sum of the plurality of sums as the target mapping distance; or
in a case of a plurality of average values are determined, using a minimum average value of the plurality of average values as the target mapping distance.

19. An electronic device, comprising:
at least one processor; and
a memory in communication with the at least one processor;
wherein the memory stores an instruction executable by the at least one processor, and the instruction, when executed by the at least one processor, enables the at least one processor to execute:
obtaining a total number of qubits N in the quantum chip structure of claim 1 to be determined; and
determining a target mapping distance of the quantum chip structure at least based on the total number of qubits N, wherein the target mapping distance is determined based on a sub-mapping distance of a pair of target qubits in the quantum chip structure, and the sub-mapping distance represents a minimum number of the couplers between one target qubit of the pair of target qubits and the other target qubit of the pair of target qubits, and wherein the target qubit of the pair of target qubits is one of: the center qubit in the ring structure of the quantum chip structure, the first qubit in the first linear structure corresponding to the center qubit Qᵢ, and the second qubit in the second linear structure corresponding to the center qubit Qᵢ, wherein i is a natural number greater than or equal to 0.

20. A non-transitory computer-readable storage medium storing a computer instruction thereon, wherein the computer instruction is used to cause a computer to execute the method of claim 12.
